(19) United States
(12) Patent Application Publication
(10) Pub. No.: US 2025/0273516 A1
(43) Pub. Date: Aug. 28, 2025

(54) MANUFACTURING METHOD OF ELECTRONIC PACKAGE

(71) Applicant: SILICONWARE PRECISION INDUSTRIES CO., LTD., Taichung City (TW)

(72) Inventors: Yi-Ling CHEN, Taichung City (TW); Kuan-Wei CHUANG, Taichung City (TW)

(21) Appl. No.: 18/913,141

(22) Filed: Oct. 11, 2024

(30) Foreign Application Priority Data
Feb. 27, 2024 (TW) 113107065

(51) Int. Cl. H01L 21/78; H01L 21/683; H01L 23/00; H01L 25/00

(52) U.S. Cl. CPC H01L 21/78; H01L 21/6836; H01L 24/81; H01L 24/83; H01L 24/92; H01L 25/00; H01L 2221/68327; H01L 2224/81203; H01L 2224/83191; H01L 2224/92143

(57) ABSTRACT

A manufacturing method of an electronic package is provided, which includes: adhering a packaging module to a surface of a carrier through a first adhesive layer, in which the packaging module has a plurality of packaging units jointly defined by first and second cutting paths; performing a pre-cutting process to cut along each of the first cutting paths; disposing at least one reinforcement structure on the surface of the first adhesive layer; adhering a plurality of optoelectronic components to the packaging units through a second adhesive layer; electrically connecting each of the optoelectronic components to a corresponding one of the packaging units; performing a singulation process to cut down the packaging module along the second cutting paths; and removing the reinforcing structure, the first adhesive layer and the carrier to form a plurality of the electronic packages.

### CROSS-REFERENCE TO RELATED APPLICATIONS

The present application is based upon and claims the right of priority to TW Patent Application No. 113107065, filed Feb. 27, 2024, the disclosure of which is hereby incorporated by reference herein in its entirety for all purposes.

### BACKGROUND

### 1. Technical Field

The present disclosure relates to a manufacturing method of an electronic package, and more particularly, to a manufacturing method of an electronic package having optoelectronic component.

### 2. Description of Related Art

With the vigorous development of the electronics industry, it has become a trend for electronic products to develop towards multi-function and high performance. In particular, the demand for data transmission has emerged largely, causing the industry to begin to use “light” instead of “electricity” as the carrier for data transmission, thereby to improve the transmission capacity, efficiency and/or distance, and to reduce the energy consumption during the transmission process. Under this background, the Co-Packaged Optical structure and the Co-Packaged Optics technology that include both the optical (photonic) components and optoelectronic components have become the trend of development for future semiconductor and packaging technologies.

FIG. 1A to FIG. 1C are schematic views illustrating a manufacturing process of a conventional semiconductor package 1, and FIG. 1B-2 is a schematic partial top view of FIG. 1B-1. A fan-out module 10 is firstly adhered to a carrier board 12 through an adhesive layer 11. An electronic IC (“EIC”) component 104 is embedded in the molding compound (“M/C” in short) 103 of the fan-out module 10. Then a first cutting is performed along the longitudinal cutting paths to remove a part of the fan-out module 10 located on the longitudinal cutting paths to form a plurality of longitudinal grooves 101, such that the adhesive layer 11 underneath is exposed from the bottom surfaces of the longitudinal grooves 101. After that, a plurality of photonic IC (PIC) components 13 are disposed over the fan-out module 10, and the PIC components 13 are coupled to the fan-out module 10 through a thermal compression process. After all the PIC components 13 have been connected to the fan-out module 10 firmly, a second cutting is performed along each of the transverse cutting paths shown in FIG. 1B-2. Finally, the carrier board 12 and the adhesive layer 11 are removed, so that a plurality of semiconductor packages 1 shown in FIG. 1C can be obtained.

However, in the aforementioned conventional processes, the heat imposed during performing the thermal compression process to the PIC component 13 will dissipate to the adhesive layer 11 and causes the adhesive layer to soften and even melt, and the downward pressing force will make the remaining fan-out module 10 compress the adhesive layer 11 after the first cutting, causing the adhesive material of the adhesive layer 11 within the longitudinal grooves 101 to deform to result in bulge 11a, as shown in FIG. 1B-1. Then, the unremoved fan-out module 10 on the transverse cutting paths 102 and/or in the nearby area will be pushed by the deformation of the adhesive layer 11 or the bulge 11a, causing fracture (as shown in FIG. 1B-2) of the fan-out module 10 or other structural damage to occur on those locations or areas. Therefore, the final product would become a defective product due to the structural issues. In addition, the adhesive layer 11 that is softened or melted by heat will also make the fan-out module 10 above it easy to slide and deviate due to the downward pressing force during the thermal pressing process, resulting in deviations in the subsequent manufacturing process, such as singulation. All these problems will adversely affect the yield rate of the above-mentioned conventional manufacturing process.

Therefore, how to overcome the above-mentioned problems of conventional techniques has become a critical issue to be solved.

### SUMMARY

In view of the aforementioned shortcomings of the prior art, the present disclosure provides a manufacturing method of an electronic package, comprising: adhering a packaging module onto a surface of a carrier through a first adhesive layer, wherein a plurality of first cutting paths and a plurality of second cutting paths are formed on the packaging module, and a plurality of packaging units are defined by the plurality of first cutting paths and the plurality of second cutting paths jointly within the packaging module; performing a pre-cutting process to cut form the top end of the packaging module along each of the first cutting paths down to the surface of the first adhesive layer, thereby to remove a part of the packaging module and to expose a part of the first adhesive layer; disposing at least a reinforcing structure on at least a part of the exposed surface of the first adhesive layer; electrically connecting a plurality of optoelectronic components to the corresponding packaging units; performing a singulation process to cut from a remaining portion of the top end of the packaging module along each of the second cutting paths down to the first adhesive layer; and removing the at least a reinforcing structure, the first adhesive layer and the carrier to form a plurality of the electronic packages, wherein each of the electronic packages comprises the packaging unit and the optoelectronic component.

In the aforementioned manufacturing method of an electronic package, the top surface of the packaging unit has a plurality of electrical connecting pads, the bottom surface of each of the optoelectronic components has a plurality of electrical connectors, and each of the electrical connectors is corresponding in position and electrically connecting to a corresponding one of the electrical connecting pads.

In the aforementioned manufacturing method of an electronic package, the optoelectronic component is subjected to a thermal compression process for the plurality of electrical connectors on the bottom surface of the optoelectronic component to penetrate a second adhesive layer and to be electrically connected to the plurality of electrical connecting pads.

In the aforementioned manufacturing method of an electronic package, the electrical connectors are solder balls.

In the aforementioned manufacturing method of an electronic package, the second adhesive layer is a Thermal Compression Non-Conductive Polymer (TCNCP) film.

In the aforementioned manufacturing method of an electronic package, the reinforcing structure comprises a Die Attached Film (DAF) disposed on the first adhesive layer and a reinforcement disposed on the DAF.

In the aforementioned manufacturing method of an electronic package, the reinforcement is a dummy die or a dummy silicon (dummy Si).

In the aforementioned manufacturing method of an electronic package, the reinforcing structure corresponds to and covers the exposed surface of the first adhesive layer after the pre-cutting process.

In the aforementioned manufacturing method of an electronic package, the reinforcing structure covers at least a part of the surface of the first adhesive layer exposed from the packaging module between any two adjacent ones of the second cutting paths after the pre-cutting process.

In the aforementioned manufacturing method of an electronic package, the optoelectronic component is a photonic IC (PIC).

In the aforementioned manufacturing method of an electronic package, the packaging module is a fan-out packaging module.

In the aforementioned manufacturing method of an electronic package, there are a plurality of semiconductor components in the packaging module, and each of the optoelectronic components is electrically connected to at least one of the semiconductor components respectively.

In the aforementioned manufacturing method of an electronic package, the semiconductor component is an electronic IC (EIC).

In the aforementioned manufacturing method of an electronic package, the carrier is a glass substrate.

By the implementation of the present disclosure, the electronic package can be manufactured by disposing a reinforcing structure on the exposed surface of the first adhesive layer after performing pre-cutting, even if the exposed surface of the first adhesive layer is imposed by the heat and compression in the subsequent processes, deformation such as bulge will not occur due to the reinforcing structure. Therefore, the structure of the packaging module, especially the packaging unit in the packaging module, will not be damaged. In the meantime, the reinforcing structure can also maintain the distances between and relative positions of the various parts of the packaging module after pre-cutting, so that even if the various parts of the packaging modules are subjected to heat and compression, displacement due to the melting or softening of the first adhesive layer underneath will not occur and the defects caused by position deviations in the subsequent processes, such as singulation, can be avoided. Therefore, the manufacturing yield of the electronic package can be improved effectively. In addition, the aforementioned manufacturing method does not require additional or new material or equipment, the existing materials and machines can be used to solve the technical problems, so there will be no substantial additional costs required.

### BRIEF DESCRIPTION OF THE DRAWINGS

FIG. 1A to FIG. 1C are schematic views illustrating the manufacturing processes of an conventional semiconductor package.

FIG. 1B-2 is a schematic top view of FIG. 1B-1.

FIG. 2A-1 to FIG. 2E are schematic views of an embodiment for the manufacturing method of an electronic package of the present disclosure.

FIG. 2A-2, FIG. 2B-2 and FIG. 2C-2 are schematic top views of FIG. 2A-1, FIG. 2B-1 and FIG. 2C-1 respectively.

FIG. 2C-3 is a schematic top view of another embodiment of FIG. 2C-2.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “third,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

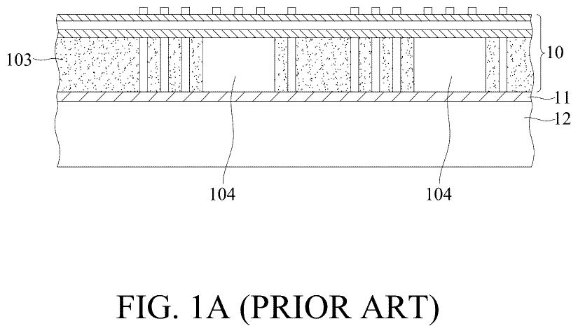

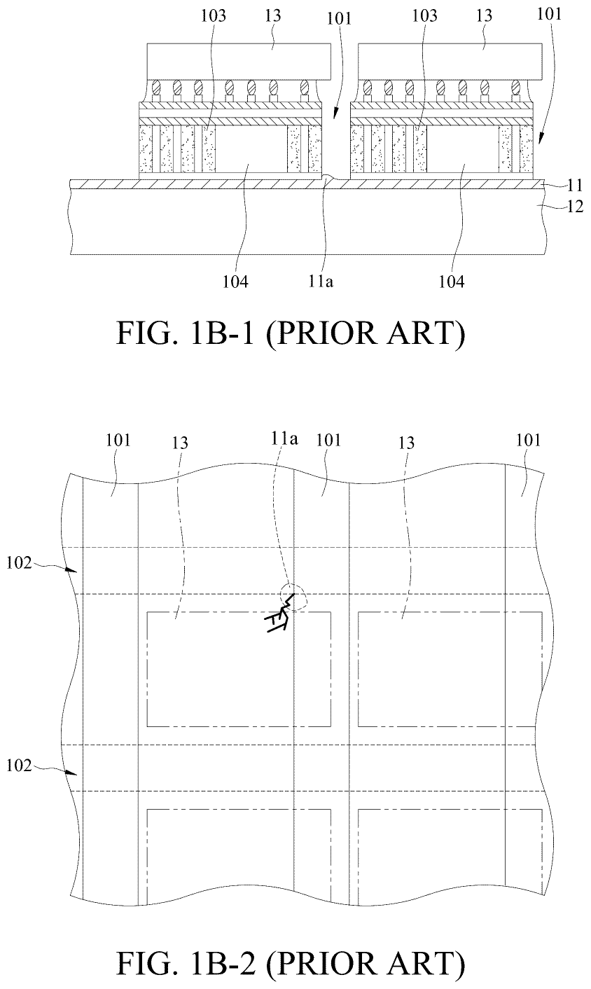

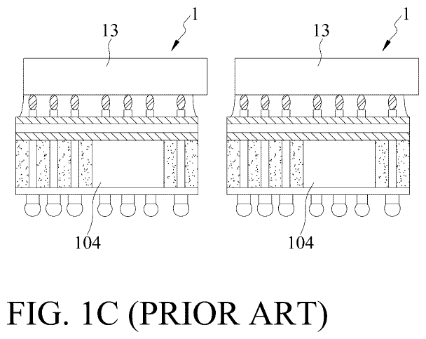

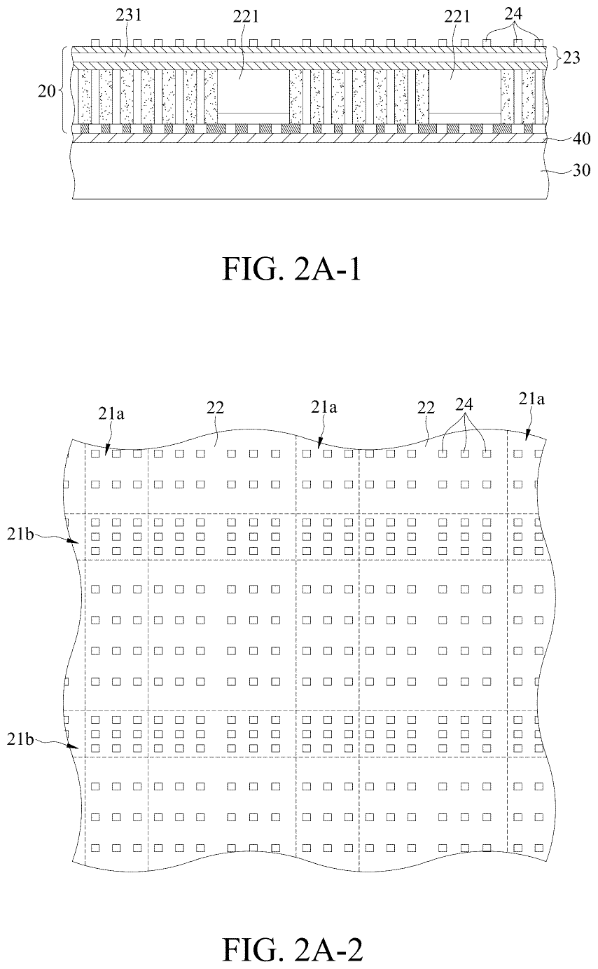

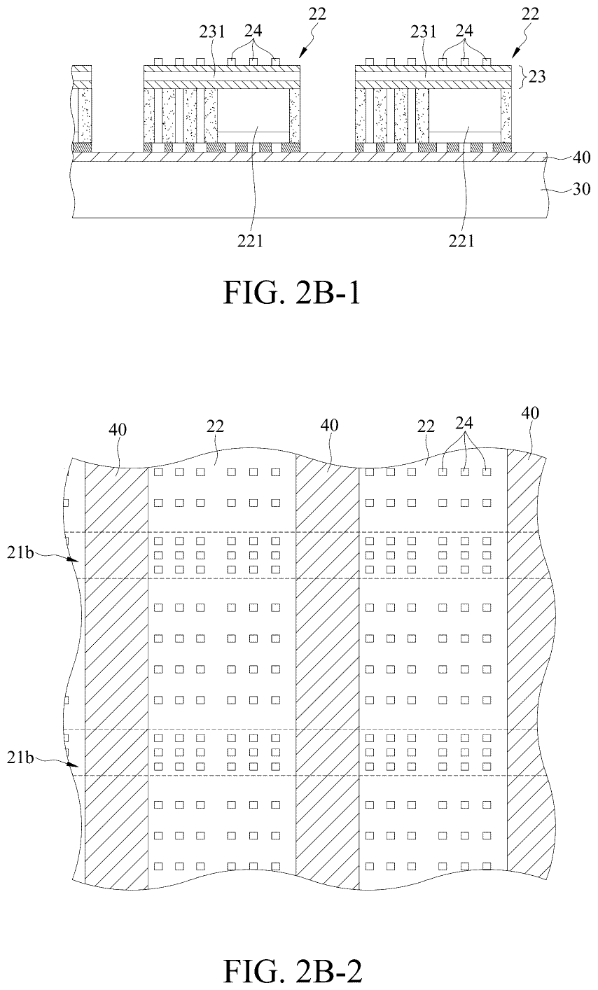

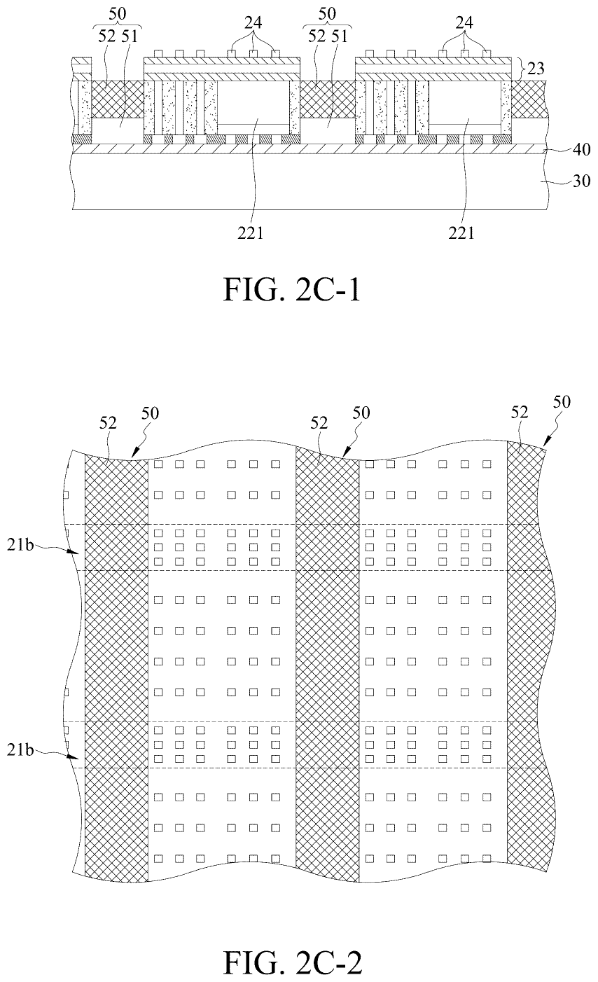

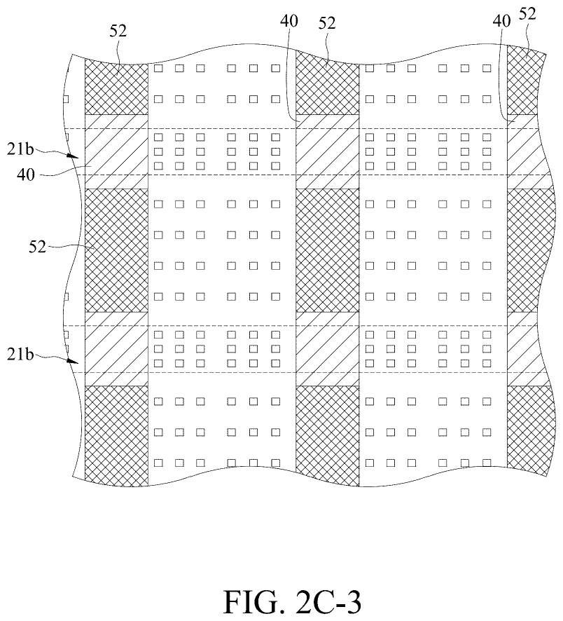

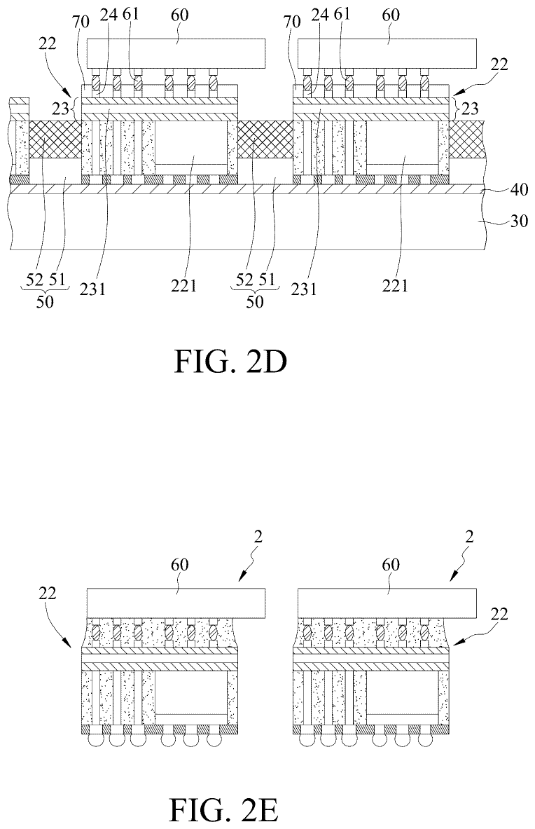

FIG. 2A-1 to FIG. 2E are schematic views of the manufacturing method of an electronic package 2 of the present disclosure, wherein FIG. 2A-2, FIG. 2B-2 and FIG. 2C-2 are schematic partial top views of FIG. 2A-1, FIG. 2B-1 and FIG. 2C-1 respectively.

As shown in FIG. 2A-1 and FIG. 2A-2, a packaging module 20 is provided at first. The packaging module 20 is adhered to a surface of a carrier 30 by a first adhesive layer 40. A plurality of first cutting paths 21a and a plurality of second cutting paths 21b are formed on the packaging module 20. The first cutting paths 21a and second cutting paths 21b are formed along different directions respectively and intersecting to each other. In an embodiment, the plurality of first cutting paths 21a extend along the longitudinal direction, and the plurality of second cutting paths 21b extend along the transverse direction. The plurality of first cutting paths 21a and the plurality of second cutting paths 21b jointly define a plurality of packaging units 22 within the packaging module 20. That is, each packaging unit 22 is surrounded and defined jointly by two adjacent ones of the first cutting paths 21a and two adjacent ones of the second cutting paths 21b in the packaging module 20.

As shown in FIG. 2B-1 and FIG. 2B-2, a pre-cutting process is performed. This process is performed to cut the packaging module 20 from the top end of the packaging module 20 along each of the first cutting paths 21a down to the surface of the first adhesive layer 40. Thus, the part of the packaging module 20 originally located underneath each of the first cutting paths 21a is removed, and the part of the first adhesive layer 40 originally located beneath each of the first cutting paths 21a is exposed from the packaging module.

Then, as shown in FIG. 2C-1 and FIG. 2C-2, a plurality of reinforcing structures 50 is disposing on at least a part of the exposed surface of the first adhesive layer 40 after performing the pre-cutting process. In other words, each of the reinforcing structures 50 is located between any two adjacent ones of the packaging units 22 and across over the first cutting path 21a separating the two adjacent ones of the packaging units 22. Preferably, the two side ends of each of the reinforcing structures 50 abut the sides of the two adjacent ones of the packaging units 22, respectively.

In FIG. 2D, a plurality of the optoelectronic components 60 are adhered to the top surfaces of the packaging units 22 by a second adhesive layer 70.

After each of the optoelectronic components 60 is adhered onto the corresponding one of the packaging units 22, each of the optoelectronic components 60 is electrically connected to the corresponding one of the packaging units 22 by thermal compression or soldering.

Then, a singulation process is performed to cut the remaining portion of the packaging module 20 from its top end downward to the first adhesive layer 40 along the second cutting path 21b shown in FIG. 2A-2. Accordingly, a plurality of the packaging units 22 are separated from each other. But at this moment, the packaging units 22 are still adhered to the first adhesive layer 40.

Finally, the aforementioned reinforcing structures 50, the first adhesive layer 40 and the carrier 30 are all removed to form a plurality of the electronic packages 2 as shown in FIG. 2E. Each of the electronic packages 2 comprises a packaging unit 22 and an optoelectronic component 60.

More specifically, the carrier 30 may be a substrate or a carrier board made of insulating material. For instance, a glass substrate may be served as the carrier 30.

Referring to FIG. 2A-1, the packaging module 20 in an embodiment may be a fan-out packaging module 20, wherein a circuit structure 23 may be included therein. The circuit structure 23 comprises at least a circuit layer 231, such as a fan-out redistribution layer (RDL). The packaging module 20 may also have a plurality of semiconductor components 221. These semiconductor components 221 are configured in a way that each of the packaging units 22 in the packaging module 20 has at least one semiconductor component 221 therein. Each of the semiconductor components 221 may be an Electronic IC (“EIC” in short), or other semiconductor chips or electronic modules that meets the functional requirements when in design.

As shown in FIG. 2C-1, the reinforcing structure 50 may include a die attached film (DAF) 51 disposed on the first adhesive layer 40 and a reinforcement element 52 disposed on the DAF 51. Preferably, the reinforcement element 52 is a dummy die or dummy silicon (Si). Besides, the reinforcement element 52 may also be made of plastics, such as polycarbonate (PC), polyethylene (PE), polyoxymethylene (POM), polyetheretherketone (PEEK), other engineering plastics, or composite materials. As long as a material can meet the requirements for the manufacturing processes, it can be used to manufacture the reinforcement element 52. Therefore, there is no additional limitation for implementation.

As shown in FIG. 2C-2, in certain embodiments, the reinforcing structure 50 may be designed to correspondingly cover the exposed surface of the first adhesive layer 40 after performing the pre-cutting process. That is, each of the reinforcing structures 50 is designed and made in a strip shape, and is disposed on the first adhesive layer 40 along each of the original first cutting paths 21a, so as to correspondingly cover all of the exposed surfaces of the first adhesive layer 40. The advantage for this design is that it can provide desired structural reinforcement effect. On the other hand, this design will also require the subsequent singulation process to cut the reinforcing structure 50 lying across each of the second cutting paths 21b at the same time.

In another embodiment shown in FIG. 2C-3, the reinforcing structure 50 is merely designed to cover a part of the exposed surface of the first adhesive layer 40 after performing the pre-cutting process. In other words, the part of the exposed surface of the first adhesive layer 40 underneath the first cutting paths 21a and located between any two adjacent ones of the second cutting paths 21b. This arrangement requires the reinforcing structure 50 to be disposed on the part of the first adhesive layer 40 that is easily to bulge and/or the part of packaging module 20 that is easily to dislocate at the time the first adhesive layer 40 is subjected to subsequent thermal compression process. As a result, this design can not only provide sufficient structural reinforcement effect, but also can save the energy consumption and decrease the depletion of cutting equipment, as well as save the process time.

In addition, a plurality of electrical connecting pads 24 are disposed on the top surface of each of the packaging units 22 in the packaging module 20 for the subsequent electrical connection with the optoelectronic component 60. As for the second adhesive layer 70 formed on the packaging module 20, it can be a thermal compression non-conductive polymer (“TCNCP” in short) film or other adhesive material that can meet the requirements of the manufacturing processes.

Each of the optoelectronic components 60 is electrically connected to at least one of the semiconductor component 221 disposed in the corresponding packaging module 20. Therefore, there are a plurality of electrical connectors 61 provided on the bottom surface of each of the optoelectronic components 60. The electrical connectors 61 are solder balls, for instance, or other types of conductive bumps. Each of the electrical connectors 61 is corresponding in position to an electrical connecting pad 24 on the packaging module 20, and is electrically connected to a corresponding one of the electrical connecting pads 24 after the second adhesive layer 70 is melted or softened by thermal compression to allow the optoelectronic components 60 to embed in the second adhesive layer 70. Thereby, each of the optoelectronic components 60 is electrically connected with a corresponding one of the packaging units 22.

In an embodiment, the optoelectronic component 60 is a photonic IC (“PIC” in short). But the optoelectronic component 60 may be other types of optoelectronic component that can meet the functional requirements.

In summary, in the manufacturing method of an electronic package of the present disclosure, the reinforcement structure is disposed on the exposed surface of the first adhesive layer after the pre-cutting process is performed, so even if the first adhesive layer is imposed by the thermal compression in the subsequent processes, deformation such as bulge will not occur on the surface of the first adhesive layer due to the reinforcing structure. Therefore, the structure of the packaging module will not be damaged, especially the packaging units. In the meantime, the reinforcing structure can also maintain the distances and relative positions between the packaging units of the packaging module after the pre-cutting process, such that, even if the packaging module is subjected to thermal compression, displacement due to the melting or softening of the first adhesive layer underneath will not occur and thus can be kept on the desired positions to avoid the defects caused by position deviations in subsequent processes, such as singulation. Therefore, the manufacturing yield of the electronic package can be improved effectively. In addition, the aforementioned manufacturing method does not require additional or new material or equipment, existing materials and equipment can be well used to solve the technical problems, and there will be no substantial additional costs produced.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A manufacturing method of an electronic package, comprising:
adhering a packaging module onto a surface of a carrier through a first adhesive layer, wherein a plurality of first cutting paths and a plurality of second cutting paths are formed on the packaging module, and a plurality of packaging units are defined by the plurality of first cutting paths and the plurality of second cutting paths jointly within the packaging module;
performing a pre-cutting process to cut from a top end of the packaging module along each of the first cutting paths down to a surface of the first adhesive layer, to thereby remove a part of the packaging module and to expose a part of the first adhesive layer;
disposing at least a reinforcing structure on at least a part of the exposed surface of the first adhesive layer;
electrically connecting a plurality of optoelectronic components to the corresponding packaging units;
performing a singulation process to cut from a remaining portion of the top end of the packaging module along each of the second cutting paths down to the first adhesive layer; and
removing the at least a reinforcing structure, the first adhesive layer and the carrier to form a plurality of electronic packages, wherein each of the electronic packages comprises the packaging unit and the optoelectronic component.

2. The manufacturing method of claim 1, wherein a top surface of each of the packaging units has a plurality of electrical connecting pads, a bottom surface of each of the optoelectronic components has a plurality of electrical connectors, and each of the electrical connectors is corresponding in position and electrically connected to a corresponding one of the electrical connecting pads.

3. The manufacturing method of claim 2, wherein the optoelectronic component is subjected to a thermal compression process for the plurality of electrical connectors on the bottom surface of the optoelectronic component to penetrate a second adhesive layer, so as for the electrical connectors to be electrically connected to the plurality of electrical connecting pads.

4. The manufacturing method of claim 3, wherein the second adhesive layer is a Thermal Compression Non-Conductive Polymer (TCNCP) film.

5. The manufacturing method of claim 1, wherein the reinforcing structure comprises a Die Attached Film (DAF) disposed on the first adhesive layer and a reinforcement element disposed on the DAF.

6. The manufacturing method of claim 5, wherein the reinforcement element is a dummy die or a dummy silicon (dummy Si).

7. The manufacturing method of claim 1, wherein the reinforcing structure corresponds in position to and covers the exposed surface of the first adhesive layer after the pre-cutting process.

8. The manufacturing method of claim 1, wherein the reinforcing structure covers at least a part of the surface of the first adhesive layer exposed from the packaging module between any two adjacent ones of the second cutting paths after the pre-cutting process.

9. The manufacturing method of claim 1, wherein the optoelectronic component is a photonic IC (PIC).

10. The manufacturing method of claim 1, wherein the packaging module is a fan-out packaging module.

11. The manufacturing method of claim 1, wherein there are a plurality of semiconductor components in the packaging module, and each of the optoelectronic components is electrically connected to at least one of the semiconductor components respectively.

12. The manufacturing method of claim 11, wherein the semiconductor component is an electronic IC (EIC).

13. The manufacturing method of claim 1, wherein the carrier is a glass substrate.
